(19) United States
(12) Patent Application Publication
(10) Pub. No.: US 2025/0357447 A1
(43) Pub. Date: Nov. 20, 2025

(54) SEMICONDUCTOR DEVICE AND METHOD OF FORMING SAME

(71) Applicant: Taiwan Semiconductor Manufacturing Co., Ltd., Hsinchu (TW)

(72) Inventors: Wensen Hung, Zhubei City (TW); Tsung-Yu Chen, Hsinchu (TW)

(21) Appl. No.: 19/283,366

(22) Filed: Jul. 29, 2025

Related U.S. Application Data
(63) Continuation of application No. 18/743,728, filed on Jun. 14, 2024.
(60) Provisional application No. 63/617,183, filed on Jan. 3, 2024.

(51) Int. Cl. H01L 25/16; H01L 21/66; H01L 23/00; H01L 23/31; H01L 23/34; H01L 23/367; H01L 23/40; H01L 23/498; H01L 23/538

(52) U.S. Cl. CPC H01L 25/16; H01L 22/12; H01L 23/34; H01L 23/3675; H01L 23/4006; H01L 23/49822; H01L 23/5384; H01L 23/3157; H01L 2023/405; H01L 23/49816; H01L 24/10; H01L 24/26

(57) ABSTRACT

In an embodiment, a method includes attaching a die to an interposer; attaching and electrically coupling the interposer to a package substrate; attaching a package lid and a first thermal interface material to the die and to the package substrate; attaching and electrically coupling the package substrate to an assembly substrate; and attaching a heat sink and a second thermal interface material to the package lid using a screw extending between the heat sink and the assembly substrate, the heat sink comprising first sensing modules in physical contact with the second thermal interface material.

### PRIORITY CLAIM AND CROSS-REFERENCE

This application is a continuation of U.S. patent application Ser. No. 18/743,728, filed Jun. 14, 2024, which application claims the benefit of U.S. Provisional Application No. 63/617,183, filed on Jan. 3, 2024, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is three-dimensional Package-on-Package (POP) technology. In a POP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 3F illustrate cross-sectional and plan views of intermediate steps in the formation of a semiconductor device, in accordance with various embodiments.

FIGS. 4A through 4C illustrate cross-sectional and plan views of a semiconductor device, in accordance with various embodiments.

FIG. 5 illustrates a cross-sectional view of semiconductor device, in accordance with various embodiments.

FIGS. 6A and 6B illustrate cross-sectional and plan views of a semiconductor device, in accordance with various embodiments.

FIGS. 7A and 7B illustrate cross-sectional and plan views of a semiconductor device, in accordance with various embodiments.

FIGS. 8A and 8B illustrate cross-sectional and plan views of a semiconductor device, in accordance with various embodiments.

FIGS. 9A through 9C illustrate cross-sectional and plan views of a semiconductor device, in accordance with various embodiments.

FIGS. 10A through 10D illustrate exemplary sensing modules, in accordance with various embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Three-dimensional integrated circuits (3D-ICs) offer many solutions to reducing physical sizes of packaged components and allowing for a greater number of components to be placed in a given chip area. One solution that 3D-IC components offer is to stack dies on top of one another and interconnect or route them through connections such as through-silicon vias (TSVs). Some of the benefits of 3D-IC, for example, include exhibiting a smaller footprint, reducing power consumption by reducing the lengths of signal interconnects, and improving yield and fabrication cost if individual dies are tested separately prior to assembly. One challenge with 3D-IC components is dealing with heat dissipation and managing thermal hotspots during operation.

Embodiments described herein relate to a semiconductor device (e.g., a semiconductor system) including a heat sink disposed over a semiconductor package such as chip-on-wafer-on-substrate (CoWoS) applications or system on integrated chip (SoIC) applications and methods of manufacturing the same. However, other suitable types of semiconductor packages may be incorporated into embodiments of the semiconductor system. In an embodiment, sensing modules are integrated into a heat sink, a package lid, and/or elsewhere in the semiconductor device. The sensing modules may be configured to measure one or more properties (e.g., pressure, displacement, stress, etc.) during formation process, such as mounting of the heat sink. The measurements (e.g., key performance indicators (KPIs)) may be monitored in order to make real-time adjustments to features of the semiconductor system. For example, the real-time adjustments prevent thermal interface materials disposed between the components from being pumped out (e.g., squeezed out or shifted) while also preventing crack formation and propagation near high performance dies (e.g., central processing units and graphics processing units). The semiconductor system may be manufactured at a greater yield and function with improved performance, reliability, stability, and longevity.

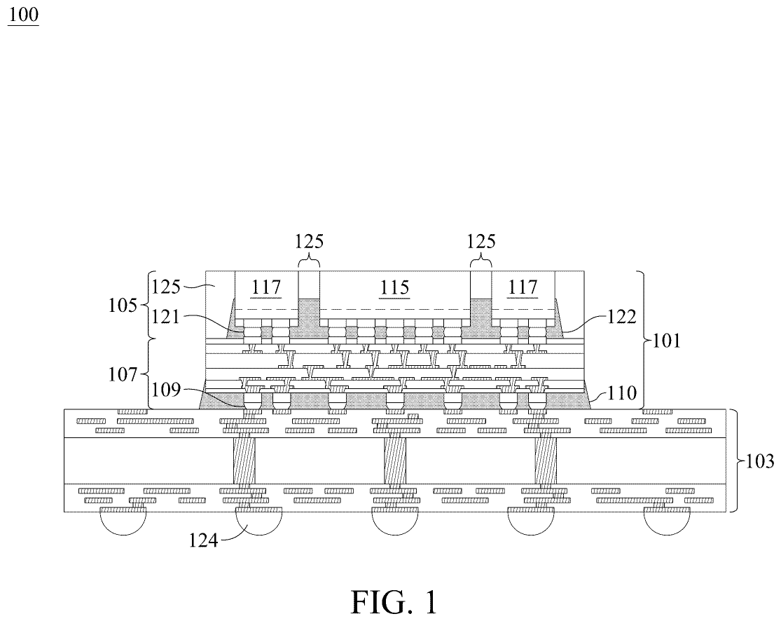

FIG. 1 illustrates a semiconductor package 100 (e.g., a CoWoS device or an SoIC device) that comprises a package component 101 (e.g., a CoW device) which is bonded to a package substrate 103. The package component 101 includes a chip module 105 (e.g., a 3D-IC module) attached to an interposer 107. The package component 101 may be referred to herein as an interposer package, a semiconductor chip package, a stacked chip package, a stacked semiconductor device package, a stacked device package, or the like. According to some embodiments, the package component 101 may include one or more first semiconductor dies 115 disposed on the interposer 107 adjacent to one or more second semiconductor dies 117.

Each of the first semiconductor dies 115 and each of the second semiconductor dies 117 may be single dies or die stacks and may be referred to as chips. The first semiconductor die 115 may be a processor, such as a system-on-chip (SoC), a central processing unit (CPU), a graphics processing unit (GPU), or the like. The second semiconductor die 117 may be a memory die such as a DRAM, high bandwidth memory (HBM), memory cube, a memory stack, or the like. Although the illustrated cross-section shows the package component 101 as having one first semiconductor die 115 and two second semiconductor dies 117, other embodiments may include any number of the semiconductor dies 115/117. The chip module 105 may comprise semiconductor stacked dies such as memory, flash, converter, sensor, logic die, and the like.

In some embodiments, the interposer 107 may be formed from a variety of semiconductor substrate materials such as silicon (Si), silicon carbide (SiC), gallium arsenide (GaAs), gallium nitride (GaN), or the like. A combination of active and/or passive devices, such as transistors, diodes, resistors, capacitors, and the like, may be formed as part of the interposer 107 to construct functional circuitries. In addition, the interposer 107 may include a series of alternating layers of conductive materials (such as copper, aluminum, alloys, doped polysilicon, combinations thereof, or the like) may be utilized between layers of dielectric material to form interconnections between the active and passive devices and also to provide access to external connections 109 (e.g., external connections of a 3D-IC module). As illustrated, the external connections 109 may include solder regions formed on under-bump metallurgies (UBMs).

Although the interposer 107 is illustrated as a redistribution structure, it should be appreciated that the interposer 107 may be a silicon interposer, a local silicon interconnect (LSI) die, or a bottom die with bonding features on opposing sides. Moreover, although the chip module 105 and the package substrate 103 are described as being attached with external connections 109 which may be solder regions, in some embodiments, the attachment process may be a direct bonding process to form dielectric-to-dielectric and metal-to-metal bonds.

In accordance with some embodiments, the chip module 105 may comprise a plurality of high performance integrated circuit dies (e.g., semiconductor dies) such as may be used in the processing of 3D smart internet TV graphics or other processing intense applications. For example, the first semiconductor die 115 may include a 3D-IC processor 115 (e.g., CPU, graphics processing unit (GPU)), and the second semiconductor dies 117 may include 3D-IC memory dies 117 (e.g., high bandwidth memory (HBM), memory cubes, memory stacks, or the like).

The semiconductor dies 115/117 may be bonded to the interposer 107 via a plurality of surface side contacts 121. In an embodiment, the surface side contacts 121 may be microbumps. An underfill material 122 (e.g., an epoxy resin) may be formed between the semiconductor dies 115/117 and the interposer 107 and around the surface side contacts 121. In some embodiments, the underfill material 122 may spread upward between adjacent semiconductor dies 115/117 toward upper surfaces through the capillary effect. After attaching the semiconductor dies 115/117, an encapsulant 125 (e.g., a molding compound) may be formed over, around, and in between the semiconductor dies 115/117. The package component 101 may be singulated from a wafer to form discrete package components 101 by, e.g., sawing through the interposer 107 and the encapsulant 125.

After singulation, the interposer 107 of the package component 101 may be bonded to the package substrate 103 using the external connections 109 (e.g., solder balls). The external connections 109 provide electrical and thermal connections between the package component 101 and the package substrate 103. Note that other methods of electrically and physically attaching the package component 101 to the package substrate 103 may be utilized, such as C4 bumps, micro-bumps, pillars, columns, or other structures formed from a conductive material such as solder, metal, or metal alloy. An underfill material 110 (e.g., an epoxy resin) may be applied between the package substrate 103 and the package component 101 (e.g., between and around the external connections 109).

In an embodiment, the package substrate 103 may be a mother substrate and may comprise a first semiconductor die such as a logic die/interposer that comprises a number of structures such as a substrate formed from a variety of semiconductor substrate materials such as silicon (Si), silicon carbide (SiC), gallium arsenide (GaAs), gallium nitride (GaN), or the like. A combination of active and/or passive devices, such as transistors, diodes, resistors, capacitors, and the like, may be formed as part of the package substrate 103 to construct functional circuitries. In addition, alternating layers of conductive materials (such as copper, aluminum, alloys, doped polysilicon, combinations thereof, or the like) may be utilized between layers of dielectric material to form interconnections between the active and passive devices and also to provide access to external connections of the package substrate 103. Through substrate vias (TSVs) may also be formed in order to provide electrical connectivity from one side of the package substrate 103 to another side of the package substrate 103. In accordance with some embodiments, the package substrate 103 is a printed circuit board (PCB) or a silicon interposer.

As illustrated, the package substrate 103 may include external connections 124, which may be, e.g., solder balls, for subsequent bonding to another substrate. The external connections 124 of the package substrate 103 may provide electrical and thermal connections between the package substrate 103 and the substrate to which the package substrate 103 is subsequently bonded. However, other methods of electrically and physically attaching the package substrate 103 to another substrate, such as C4 bumps, micro-bumps, pillars, columns, or other structures formed from a conductive material such as solder, metal, or metal alloy, may be utilized to facilitate electrical, physical, and thermal connectivity between the package substrate 103 and the substrate to which the package substrate 103 is bonded.

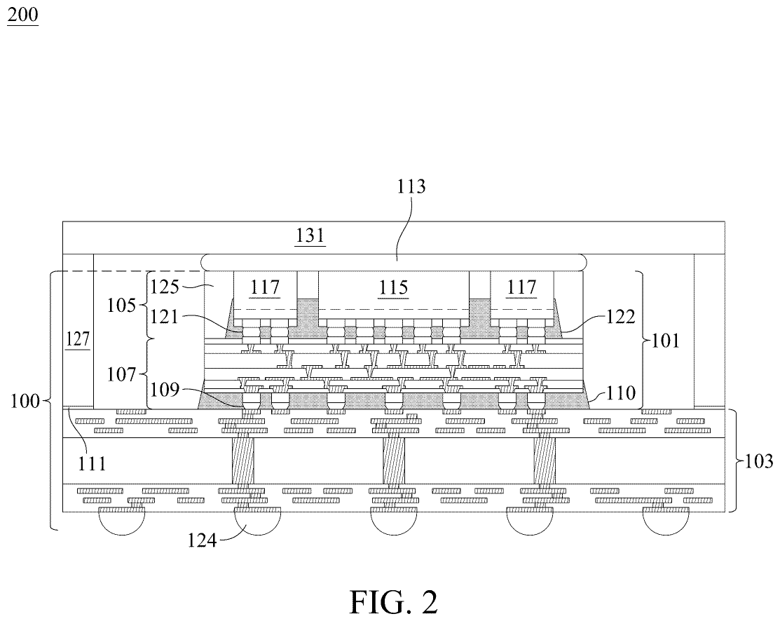

FIG. 2 illustrates formation of a packaged arrangement 200, in accordance with various embodiments. The packaged arrangement 200 may include thermal interface materials (TIMs) such as a thermal interface adhesive 111 and a first thermal interface material 113, and a package lid 131 attached to the semiconductor package 100. For example, the thermal interface adhesive 111 is applied to a top surface of the package substrate 103, the first thermal interface material (TIM) 113 is applied to a top surface of the chip module 105, and the package lid 131 is applied to the package substrate 103 and the chip module 105 using the thermal interface adhesive 111 and the first thermal interface material 113, respectively.

In an embodiment, the thermal interface adhesive 111 may be a viscous, silicone compound similar to the mechanical properties of a grease or a gel. The thermal interface adhesive 111 is used to improve electrical and/or thermal conduction by filling in microscopic air pockets created between minutely uneven surfaces, such as the region between surfaces of the package substrate 103 and overlying materials; the thermal interface adhesive 111 may also have a thermal conductivity (i.e., “k value”) in Watts per meter-Kelvin (W/mK) of between about 1 W/mK and about 10 W/mK, such as about 4 W/mK, for example.

In some embodiments the thermal interface adhesive 111 is a metal-based thermal paste containing silver, nickel, or aluminum particles suspended in the silicone grease. In other embodiments non-electrically conductive, ceramic-based pastes, filled with ceramic powders such as beryllium oxide, aluminum nitride, aluminum oxide, or zinc oxide, may be applied. In other embodiments, instead of being a paste with a consistency similar to gels or greases, the thermal interface adhesive 111 may, instead be a solid material. In this embodiment the thermal interface adhesive 111 may be a thin sheet of a thermally conductive, solid material. In a particular embodiment the thermal interface adhesive 111 that is solid may be a thin sheet of indium, nickel, silver, aluminum, combinations and alloys of these, or the like, or other thermally conductive solid material. Any suitably thermally conductive material may also be utilized, and all such materials are fully intended to be included within the scope of the embodiments. The thermal interface adhesive 111 is injected or placed on the package substrate 103 around but laterally separated from the chip module 105.

The first thermal interface material 113 may be applied to the chip module 105 in order to provide a thermal interface between the chip module 105 and the overlying package lid 131. In an embodiment the first thermal interface material 113 may be similar to the thermal interface adhesive 111 and may be applied at the same time as the thermal interface adhesive 111, although the first thermal interface material 113 may also be different from the thermal interface adhesive 111.

In an embodiment the first thermal interface material 113 may be applied in either a solid, grease, or gel consistency or may be applied as a film type TIM, such as a carbon nanotube based (CNT) or a graphite based TIM. According to some embodiments, the first thermal interface material 113 may have a thermal conductivity (i.e., “k value”) in Watts per meter-Kelvin (W/mK) of between about 1 W/mK and about 30 W/mK, such as about 4 W/mK, for example. However, any suitable value of thermal conductivity may be used. In some embodiments, the first thermal interface material 113 may have a footprint that is substantially the same or larger than the area of an upper surface of the chip module 105.

Still referring to FIG. 2, the package lid 131 (e.g., a thermally conductive ring and a capping portion) is attached wherein a thermally conductive ring 127 (e.g., a conductive ring) of the package lid 131 is attached to the thermal interface adhesive 111. As illustrated, the thermal interface adhesive 111 and the thermally conductive ring 127 may both be laterally separated from the package component 101 and encircle the package component 101 forming a cavity or gap within inner walls of the thermally conductive ring 127. In an embodiment, the lateral separation between the thermally conductive ring 127 from the package component 101 may be substantially equidistant around each side of the package component 101. In other embodiments, the lateral separation between the thermally conductive ring 127 and the package component 101 may be different around each side of the package component 101. In an embodiment, the thermally conductive ring 127 is used to provide a thermal path from the thermal interface adhesive 111 to the rest of the package lid 131.

In an embodiment, the thermally conductive ring 127 may comprise a thermally conductive material, such as a material having a thermal conductivity (i.e., “k value”) in Watts per meter-Kelvin (W/mK) greater than about 1 W/Mk, such as a thermal conductivity between about 10 W/mK and about 400 W/mK, such as about 380 W/mK. However, any suitable thermal conductivity may be used. In a particular embodiment, the thermally conductive ring 127 may comprise a metal such as copper, although any other suitable metal, such as aluminum or the like, may also be used. Similarly, dielectric materials, such as silicone, may also be utilized as long as they are suitable for the transmission of heat from the package substrate 103 to the package lid 131.

In some embodiments, the thermally conductive ring 127 may be a distinct component from the package lid 131. In addition, the thermally conductive ring 127 and the thermal interface adhesive 111 may be placed on the package substrate 103 before attaching the package component 101 (e.g., the interposer 107 and the chip module 105) to the package substrate 103. In some such embodiments, the thermal interface adhesive 111 may serve as a flow barrier for the subsequently formed underfill 110 of the interposer 107. Further, the package lid 131 may be attached to the thermally conductive ring 127 using another thermal interface adhesive (not specifically illustrated), which may be applied similarly as described in connection with the thermal interface adhesive 111.

In another embodiment, instead of having a single thermally conductive ring 127 that encircles the package component 101 on the package substrate 103, multiple thermally conductive rings 127 may be used. In this embodiment a plurality of thermally conductive rings 127 are placed on the thermal interface adhesive 111, for example, with one ring being within (e.g., concentrically within) another thermally conductive ring 127. By using multiple thermally conductive rings 127 instead of a single thermally conductive ring, additional support may be provided.

In an embodiment, a heat treatment may be performed in which the thermal interface adhesive 111 is in a liquid or semi-solid form, in order to cure the thermal interface adhesive 111 such that the thermal interface adhesive 111 becomes solid. The heat treatment may be performed by placing the thermal interface adhesive 111 into e.g., a furnace and heating the thermal interface adhesive 111. However, the curing is not intended to be limited as such. Rather, any suitable method for curing the thermal interface adhesive 111, such as irradiating the thermal interface adhesive 111 or even allowing the thermal interface adhesive 111 to cure at room temperature may also be utilized. All suitable methods for curing the thermal interface adhesive 111 are fully intended to be included within the scope of the embodiments.

As discussed above, FIG. 2 also illustrates the placement of the package lid 131 over the package substrate 103, the chip module 105 (e.g., the package component 101), and the thermally conductive ring 127 (if distinct from the package lid 131). In an embodiment, the package lid 131 is deployed to protect the package substrate 103, the package component 101, and any underlying substrate, and also to help spread the heat generated from the package substrate 103 and the package component 101 over a larger area, especially for high power applications such as 3D-IC package applications (e.g., SoIC and/or chip-on-wafer-on-substrate (CoWoS)).

In some embodiments, the package lid 131 may comprise copper, aluminum, other metals, alloys, combinations thereof, or other material of high electrical and thermal conductivities. According to some embodiments, the package lid 131 may have a thermal conductivity (i.e., “k value”) in Watts per meter-Kelvin (W/mK) in a first thermal spreading direction (e.g., parallel to a major surface of the package lid 131) of between about 10000 W/mK and about 20000 W/mK, for example, and in a second thermal spreading direction (e.g., through a depth of the package lid 131) of between about 200 W/mK and about 7000 W/mK, for example. However, any suitable values of thermal conductivity may be used.

The package lid 131 comprises materials that possess a high thermal conductivity and a low coefficient of thermal expansion (CTE). According to an embodiment, the package lid 131 comprises a material such as copper, copper alloy, copper tungsten (CuW), or aluminum-silicon-carbide (AlSiC). Other suitable thermally conductive materials and/or thermally insulating materials may also be used. In an embodiment, the package lid 131 has a low coefficient of thermal expansion substantially similar to a low coefficient of thermal expansion of the package substrate 103.

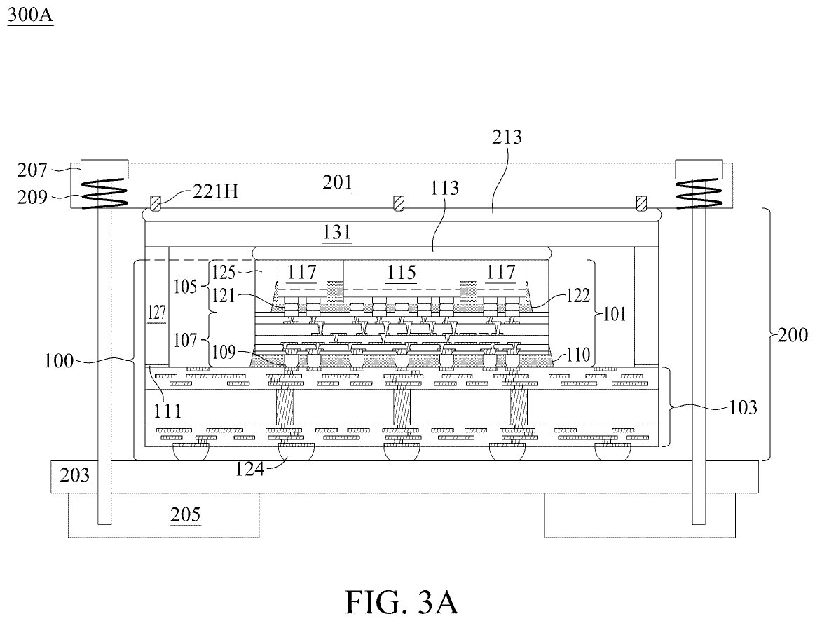

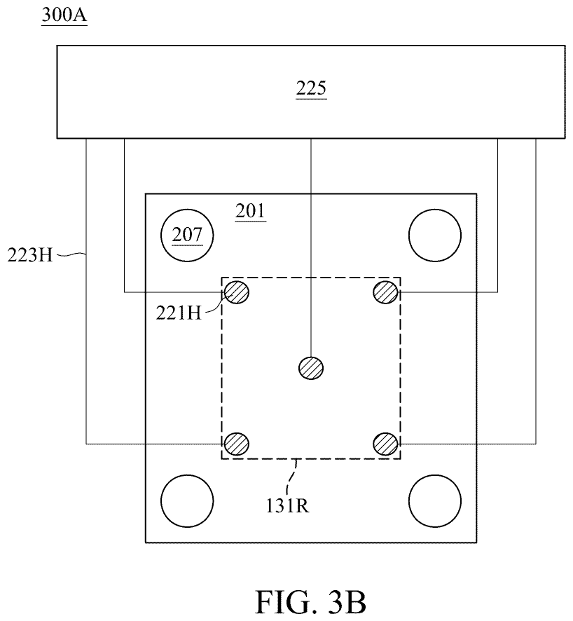

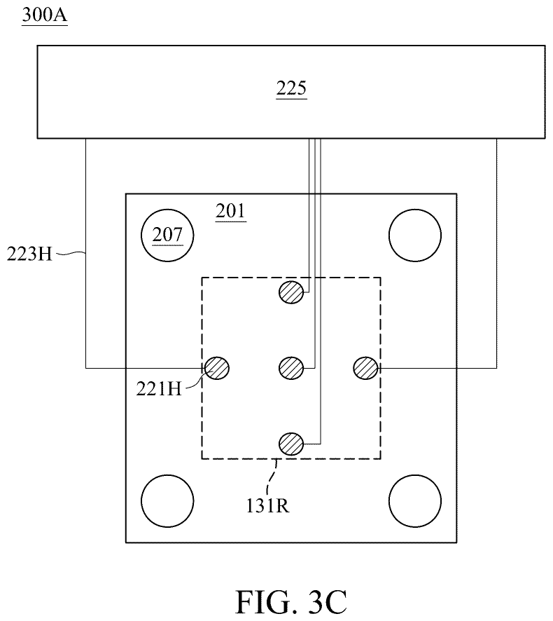

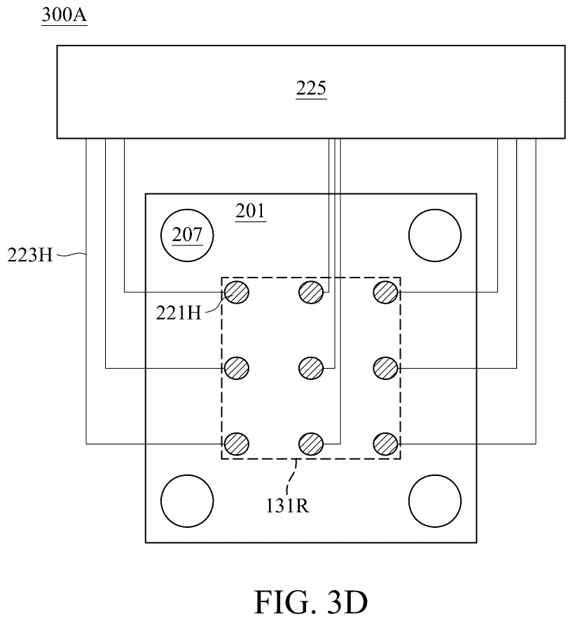

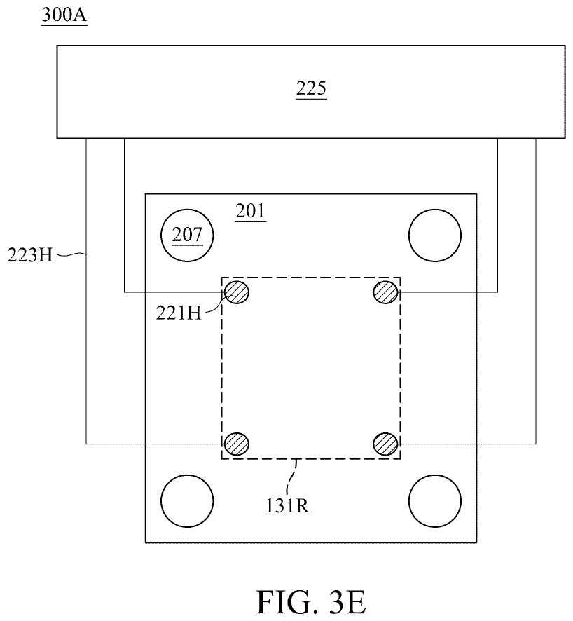

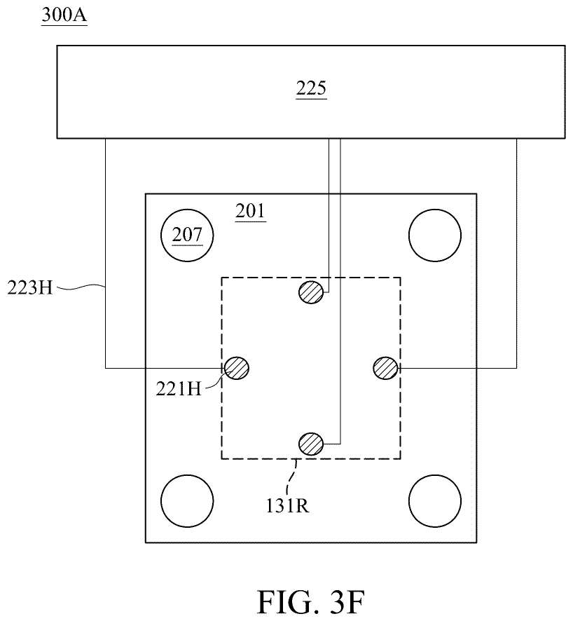

In FIGS. 3A-3F, a package system assembly 300A is formed by mounting a heat sink 201 and an assembly substrate 203 to the packaged arrangement 200 (e.g., the semiconductor package 100 and the package lid 131). In an embodiment, the heat sink 201 may be mounted over and thermally coupled to the package lid 131, thereby being indirectly thermally coupled to the chip module 105 and the package substrate 103 of the packaged arrangement 200. In addition, the packaged arrangement 200 may be attached to the assembly substrate 203 (e.g., a printed circuit board (PCB)) with a back plate 205 attached thereto. A plurality of screws 207 may be utilized to secure the heat sink 201 to the assembly substrate 203 and the back plate 205, although any suitable mechanism may be used. In addition, springs 209 embedded in the heat sink 201 and around the screws 207 may support the heads of the screws 207. As such, the springs 209 introduce flexibility between the screws 207 and the heat sink 201 while also contributing stability and rigidity.

In various embodiments, the package substrate 103 is coupled both electrically and physically to the assembly substrate 203 on a side of the package substrate 103 opposite the package component 101. The assembly substrate 203 provides a structural base and an electrical interface from the package substrate 103 and/or the package component 101 to other devices and systems. For example, the assembly substrate 203 may work to interconnect various electrical components to each other in order to provide a desired functionality for a user. In some embodiments (not specifically illustrated), the assembly substrate 203 may be bonded to other electrical elements, such as resistors, capacitors, signal distribution circuitry, combinations of these, or the like. These electrical elements may be active, passive, or a combination thereof. In other embodiments, the assembly substrate 203 may be a non-electrical substrate that is free from (or electrically isolated from) both active and passive electrical elements. All such combinations are fully intended to be included within the scope of the embodiments.

The heat sink 201 may be formed using materials exhibiting high thermal conductivity such as aluminum, copper, other metals, alloys, combinations thereof, and the like, and aids in the cooling of the package substrate 103 and the package component 101 by increasing a given surface area to be exposed to a cooling agent surrounding it such as air or liquid. The heat transfer mechanisms occur through the convection of the surrounding air, the conduction through the air, and radiation. For example, the heat sink 201 may exhibit a much greater surface area for convection compared with the surface area of the package lid 131, the package substrate 103, and the package component 101. In some embodiments, the heat sink 201 may achieve this by employing a large number of fins in the form of a matrix of geometrically shaped pins or an array of straight or flared fins. In another example, such as where convection is low, a matted-black surface color may radiate much more efficiently than shiny, metallic colors in the visible spectrum. Any suitable form for the heat sink may be utilized.

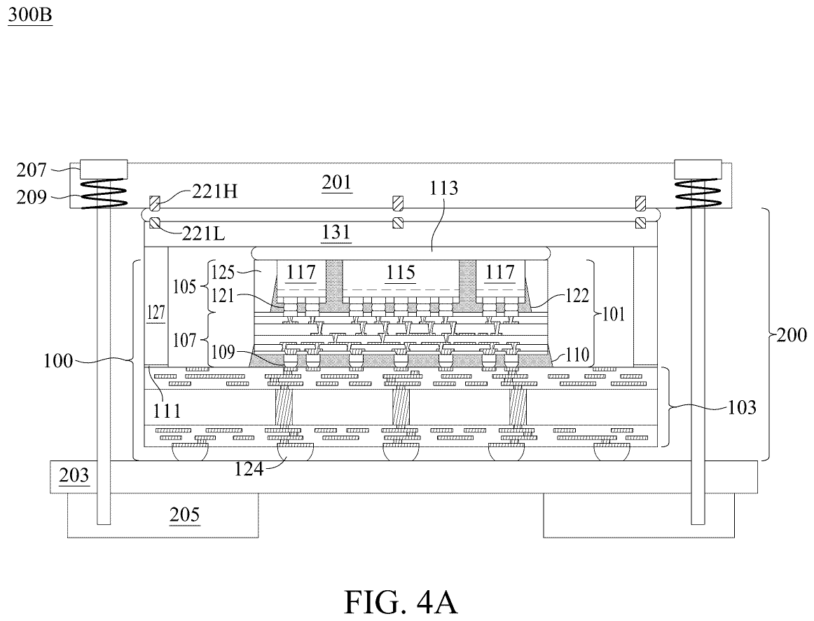

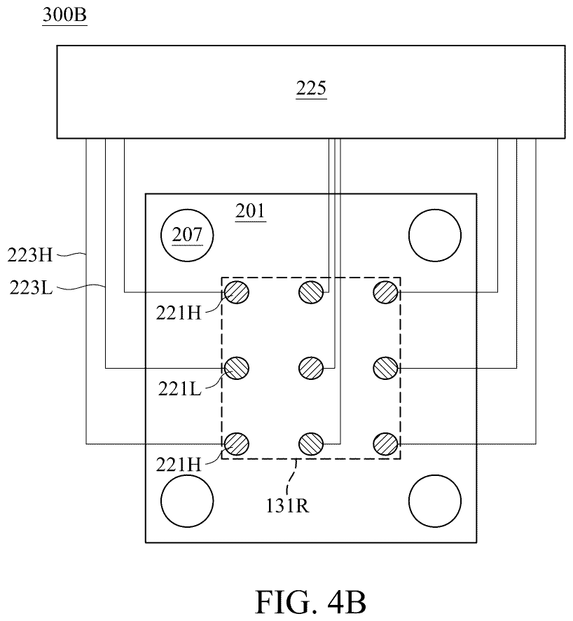

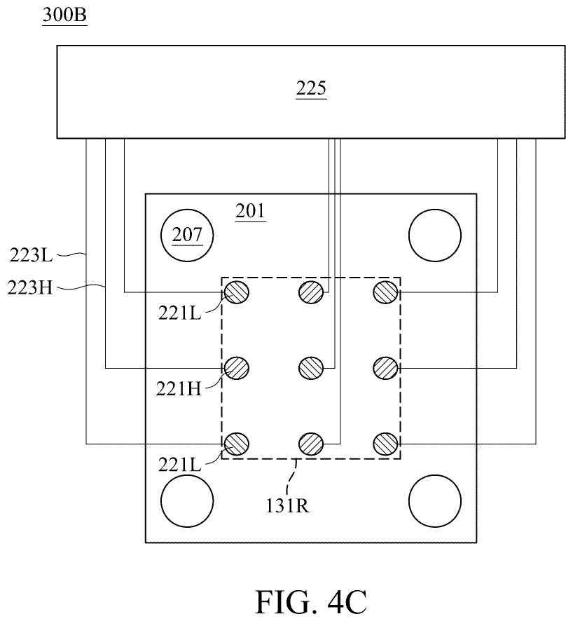

As noted above, the heat sink 201 of the package system assembly 300A may be an air cooling system having certain additional features described herein although not necessarily illustrated. In some embodiments, the heat sink 201 or the thermally conductive ring 127 may be configured to include fins which direct air flow into and through the heat sink 201. For example, heat from the semiconductor package 100 is transferred to thermal transfer components (e.g., the thermal interface materials 113/213 and the lid 131), and the air removes heat from the thermal transfer components. The heat sink 201 may further employ a series of fans and/or other devices to create or bolster a convection current to direct heated air away from the thermal transfer components while cooler air is flowed toward the thermal transfer components. In accordance with various embodiments, the sensing modules 221H of the heat sink 201 are located along the interface between the heat sink 201 and the thermal transfer components (e.g., the second thermal interface material 213 or the lid 131). As discussed below in connection with other embodiments, the lid 131 may also or alternatively include sensing modules (see, e.g., FIGS. 4A-4C).

As noted above, the heat sink 201 of the package system assembly 300A may be a liquid cooling system having additional features described herein although not necessarily illustrated. In some embodiments, the heat sink 201 may similarly include a number of fins which direct flow of a liquid coolant through the heat sink 201. For example, heat from the semiconductor package 100 is transferred to thermal transfer components (e.g., the thermal interface materials 113/213 and the lid 131), and the liquid coolant removes heat from the thermal transfer components. The heat sink 201 may further employ a pump to flow heated liquid coolant away from the thermal transfer components while cooler liquid coolant is flowed toward the thermal transfer components. In some embodiments, the heat sink 201 further includes a cold plate to cool the heated liquid coolant shortly after flowing away from the thermal transfer components and a reservoir or tank from which cool liquid coolant is pumped to the thermal transfer components. In addition, the cold plate may be incorporated in the heat sink 201 or incorporated in the lid 131. In these respective cases, the sensing modules 221H may be located on bottom surfaces of the heat sink 201 and/or the lid 131 (see, e.g., FIGS. 4A-4C) in proximity to the semiconductor package 100. In other embodiments, the heated liquid coolant exits the heat sink 201 while cooler liquid coolant enters the heat sink 201 from an external source.

Still referring to FIGS. 3A-3F, the heat sink 201 may have a contact area that is thermally coupled to the package lid 131 through a second thermal interface material (TIM) 213. The second thermal interface material 213 may be placed on a top surface of the package lid 131 (or a lower surface of the heat sink 201) in order to provide a thermal interface between the package lid 131 and the overlying heat sink 201. In an embodiment the second thermal interface material 213 may be similar to the first thermal interface material 113, although the second thermal interface material 213 may also be different from the first thermal interface material 113. According to some embodiments, the second thermal interface material 213 may have a thermal conductivity (i.e., “k value”) in Watts per meter-Kelvin (W/mK) of between about 5 W/mK and about 10 W/mK, for example. However, any suitable value of thermal conductivity may be used.

As illustrated, the heat sink 201 may include one or more embedded sensing modules 221H (e.g., heat sink sensing modules) configured to measure properties relating to the condition of the package system assembly 300A. For example, the first sensing modules 221H may measure pressure, force, displacement, stress, strain, temperature, humidity, chemistry, the like, or combinations thereof. For the sake of simplicity, embodiments discussed herein may refer to the sensing modules as being pressure sensors, however, sensors for any of the above-discussed metrics may be utilized.

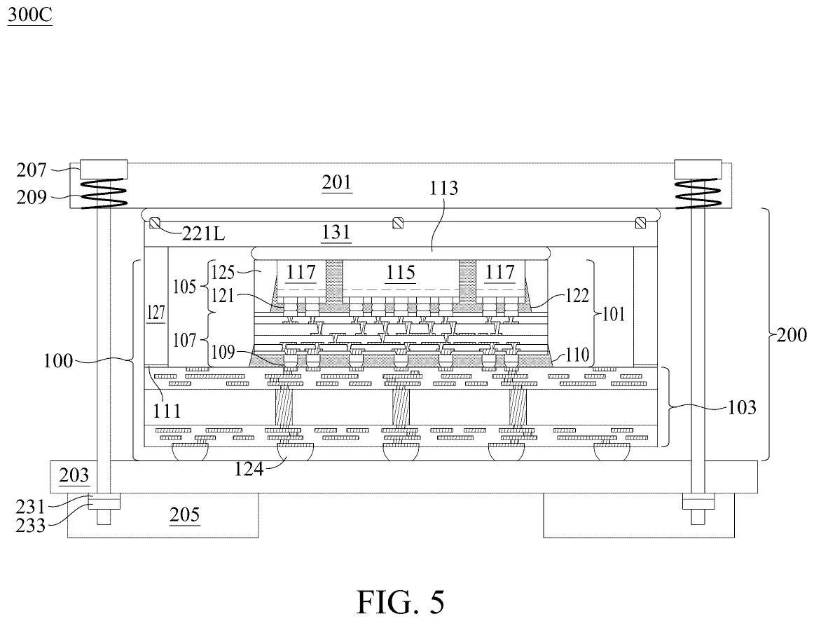

In some embodiments, during the mounting of the heat sink 201, the sensing modules 221H take measurements to determine whether the mounting is straight and even. For example, the pressure readings provide real-time assessment of whether different parts of the package system assembly 300A are imbalanced. As such, adjustments can be made automatically and/or manually to rebalance or maintain balance during the mounting process. For example, the measurements may be displayed on a screen for a user to interpret and take manual action in response to the measurements. Alternatively, the measurements (whether displayed or not) may be sent to a controller which takes automatic action in response to the measurements. In accordance with some embodiments, such adjustments may include tightening or loosening some of the screws 207 and/or bolts 233 (see FIG. 5), repositioning (e.g., straightening) the thermal interface material(s) 113/213, repositioning (e.g., straightening) the heat sink 201, stopping and restarting the heat sink 201 mounting process, and any other useful activities.

The mounting process is benefited in numerous ways. For example, the first and second thermal interface materials 113/213 remain aligned and are prevented from sliding out (e.g., pump-out) or shifting. In addition, this ensures that even pressure is applied to the chip module 105 from the overlying thermal interface materials 113/213, package lid 131, and heat sink 201. As a result, an entire surface of the chip module 105 receives even pressure and cooling, which prevents crack formation and propagation (e.g., particularly proximately to the high performance dies, such as CPUs and GPUs). The sensing modules 221H permit real-time measurements during the mounting process, which therefore permit real-time adjustments to prevent damage or weakening of the package system assembly 300A. The bond line thickness of features such as the thermal interface materials 113/213 may be maintained at a constant, and stress levels across the chip module 105 can be maintained sufficiently within safety protocols. The resulting package system assembly 300A may be manufactured at a higher yield and maintain improved performance and longevity.

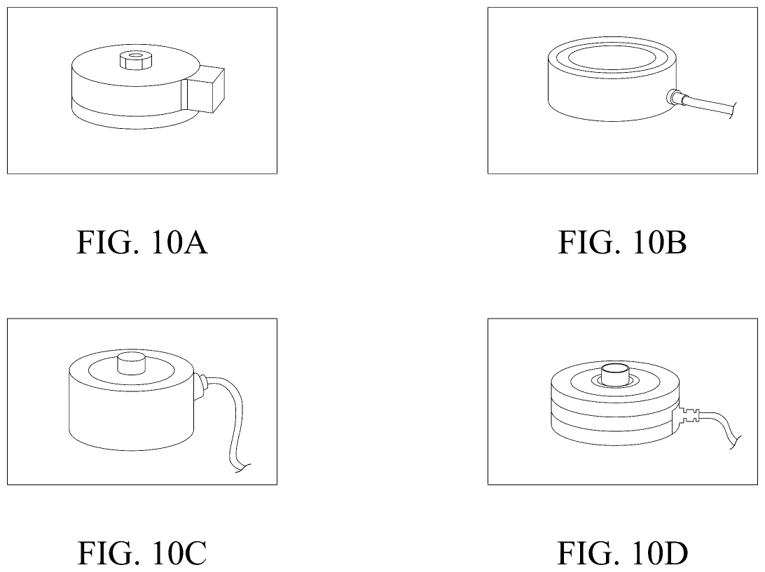

It should be appreciated that the sensing modules 221H may achieve these benefits through a variety of measurements. For example, the sensing modules 221H can take measurements relating to pressure, force, displacement, stress, and strain, e.g., using sensing devices which may be pneumatic (see FIG. 10A), hydraulic (see FIG. 10B), strain gauge (see FIG. 10C), and/or capacitance cells (see FIG. 10D). The sensing modules 221H may also or alternatively be used to measure temperature, humidity, and/or chemistry (or other material and chemical properties) to detect unevenness or other factors that may otherwise reduce the success of the mounting process.

In accordance with various embodiments, the sensing modules 221 may be electrically connected to a monitoring system 225 with wires. In some embodiments, the sensing modules 221H may be wirelessly connected to the monitoring system 225. Although embodiments discussed above or below may be described with respect to the sensing modules 221H being wired or wireless, any suitable combination of wired and wireless connection may be utilized for the sensing modules 221H. In the case of wireless sensing modules 221H, a load measurement of the sensing module 221 may be monitored directly, such as using a handheld probe. In addition, the sensing module 221H may be coupled to a transfer device (not specifically illustrated) which may be part of the monitoring system 225 or be capable of sending data to the monitoring system 225 or a cloud storage. As such, the load measurement data can be transmitted from the sensing module 221H to the transfer device which then uploads the load measurement data to the monitoring system 225 or storage system.

FIGS. 3B-3F are plan views illustrating exemplary layouts or configurations of the sensing modules 221H along the lower surface of the heat sink 201, in accordance with some embodiments. The selected configuration may be any suitable pattern to facilitate measurement of the desired properties. The sensing modules 221H may deliver data through wires 223H to a monitoring system 225. In some embodiments (not specifically illustrated), the monitoring system 225 may be attached to the package substrate 103 or the assembly substrate 203. The wires 223H may extend through the heat sink 201 or along the lower surface of the heat sink 201 toward one or more sides of the heat sink 201. Although not specifically illustrated, the monitoring system 225 may be electrically connected to a computing system which may include a controller. The controller may be connected to devices that are configured to adjust features of the package system assembly 300A or to adjust parameters of the environment in response to the measurements.

In FIGS. 3B-3F, a lid surface region 131R depicts a projection (e.g., footprint or boundary) of the package lid 131 (or of the second TIM 213). As illustrated, the sensing modules 221H may be located within the lid surface region 131R of the heat sink 201. FIG. 3B illustrates the sensing modules 221H arranged near corners and at a center of the lid surface region 131R. FIG. 3C illustrates the sensing modules 221H arranged along or near sides and at the center of the lid surface region 131R. FIG. 3D illustrates the sensing modules 221H arranged near the corners, along or near the sides, and at the center of the lid surface region 131R (e.g., a union or combination of the configurations depicted in FIGS. 3B and 3C). FIG. 3E illustrates a variation of the configuration depicted in FIG. 3B wherein the sensing modules 221H are arranged near corners of the lid surface region 131R while the center is free of the sensing modules 221H. FIG. 3F illustrates a variation of the configuration depicted in FIG. 3C wherein the sensing modules 221H are arranged along or near the sides of the lid surface region 131R while the center is free of the sensing modules 221H. It should be appreciated that the illustrated embodiments represent exemplary configurations, and any suitable arrangement of the sensing modules 221H may be utilized.

FIGS. 4A-4C illustrate a package system assembly 300B wherein the package lid 131 includes one or more sensing modules 221L (e.g., lid sensing modules), in accordance with additional embodiments. The package system assembly 300B may be formed similarly and may comprise similar components as described above, unless otherwise stated. The sensing modules 221L may be configured to measure one or more of the properties discussed above in connection with the sensing modules 221H. As illustrated, the heat sink 201 of the package system assembly 300B may also include the sensing modules 221H. In some embodiments (not specifically illustrated), the heat sink 201 may be free of the sensing modules 221H.

FIGS. 4B and 4C are plan views illustrating exemplary layouts or configurations of the sensing modules 221H along the lower surface of the heat sink 201 and the sensing modules 221L along the upper surface of the package lid 131, in accordance with some embodiments. The selected configuration may be analogous to embodiments discussed above or any suitable pattern to facilitate measurement of the desired properties. For example, the sensing modules 221L may measure similar or different properties as the sensing modules 221H. The sensing modules 221L may deliver data through wires 223L to the same monitoring system 225 that receives the data from the sensing modules 221H or to a separate monitoring system. The wires 223L may extend through the second thermal interface material 213 and through the heat sink 201 (e.g., alongside the wires 223H) or along the upper surface of the package lid 131 toward one or more sides of the package lid 131.

FIG. 4B illustrates the sensing modules 221H arranged on the lower surface of the heat sink 201 near the corners and at the center of the lid surface region 131R and the sensing modules 221L arranged on the upper surface of the package lid 131 along or near the sides of the lid surface region 131R. Conversely, FIG. 4C illustrates the sensing modules 221L arranged on the upper surface of the package lid 131 near the corners and at the center of the lid surface region 131R and the sensing modules 221H arranged on the lower surface of the heat sink 201 along or near the sides of the lid surface region 131R. In various embodiments (not specifically illustrated), each set of the sensing modules 221H/221L may have other suitable configurations (e.g., including those discussed in previous embodiments), and the respective configurations may be complementary or overlapping.

FIG. 5 illustrates a package system assembly 300C with pressure sensors 231 around the screws 207 and sandwiched between the assembly substrate 203 and bolts 233 (e.g., screw bolts or nuts), in accordance with various embodiments. The package system assembly 300C may be formed similarly and may comprise similar components as described above, unless otherwise stated. The pressure sensors 231 may be configured to measure pressures or pressure changes caused by forces acting evenly or unevenly on the screws 207 in relation to the heat sink 201 and/or the assembly substrate 203. The package system assembly 300C may also include sensing modules 221L (as illustrated) and/or sensing modules 221H (not specifically illustrated) as described above in connection with previous embodiments. Although not specifically illustrated, the pressure sensors 231 may be wirelessly connected to the monitoring system or connected with wires, analogously as described in connection with other embodiments (e.g., externally from the package system assembly 300C or through the assembly substrate 203).

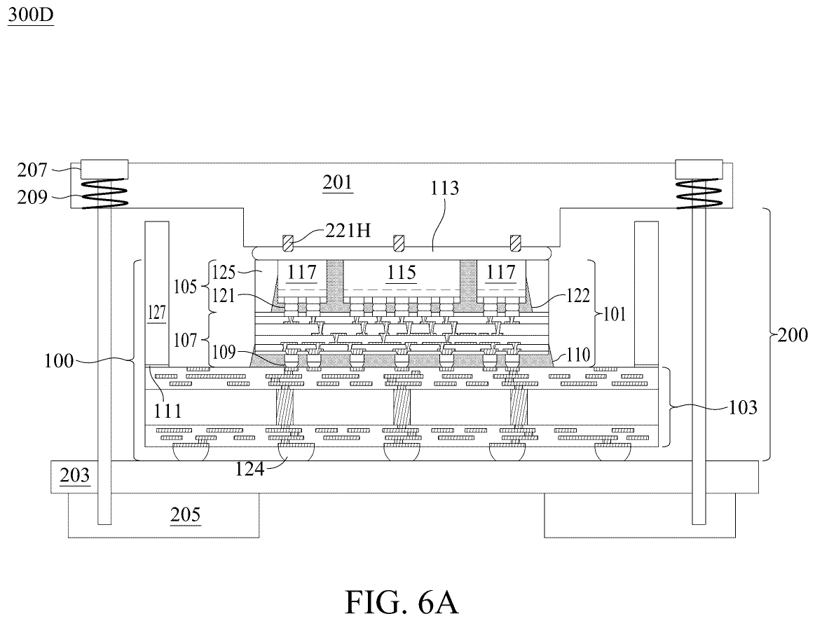

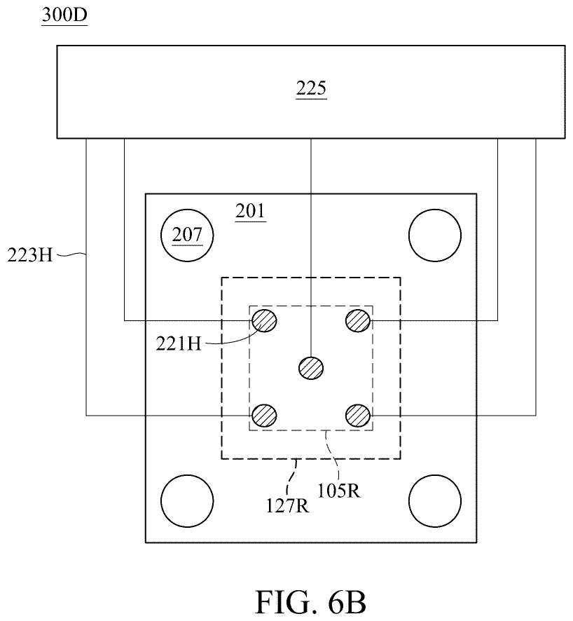

FIGS. 6A-6B illustrate a lidless package system assembly 300D wherein the heat sink 201 includes sensing modules 221H adjacent to the first thermal interface material 113, in accordance with additional embodiments. The package system assembly 300D may be formed similarly and may comprise similar components as described above, unless otherwise stated. In some embodiments, the heat sink 201 may protrude downward from a major surface to physically contact the first thermal interface material 113. As such, the sensing modules 221H may be located along the lowermost surface of the heat sink 201. As illustrated, a gap may remain between the thermally conductive ring 127 and the heat sink 201 to prevent the thermally conductive ring 127 from affecting the sensing modules 221H. In some embodiments (not specifically illustrated), the heat sink 201 may make physical contact with a top surface of the thermally conductive ring 127 to give the package system assembly 300D additional stability.

FIG. 6B is a plan view illustrating an exemplary layout or configuration of the sensing modules 221H along the lowermost surface of the heat sink 201, in accordance with some embodiments. The selected configuration may be analogous to embodiments discussed above or any suitable pattern to measure the desired properties. The sensing modules 221H may deliver data through the wires 223H to a monitoring system 225. The wires 223H may extend through the heat sink 201 or along the lowermost surface of the heat sink 201 toward one of the sides of the heat sink 201.

In the illustrated embodiment, a chip module surface region 105R depicts a projection (e.g., footprint or boundary) of the chip module 105 (or of the first thermal interface material 113 or of the downward protrusion of the heat sink 201). In addition, a conductive ring surface region 127R depicts a projection (e.g., footprint or boundary) of the thermally conductive ring 127. As illustrated, the sensing modules 221H may be located within the chip module surface region 105R of the heat sink 201. FIG. 6B illustrates the sensing modules 221H arranged near corners and at a center of the chip module surface region 105R. As discussed above, the configuration of the sensing modules 221H may be similar to configurations discussed above in connection with previous embodiments, albeit being located within or along the chip module surface region 105R (e.g., as opposed to the lid surface region 131R of previous embodiments).

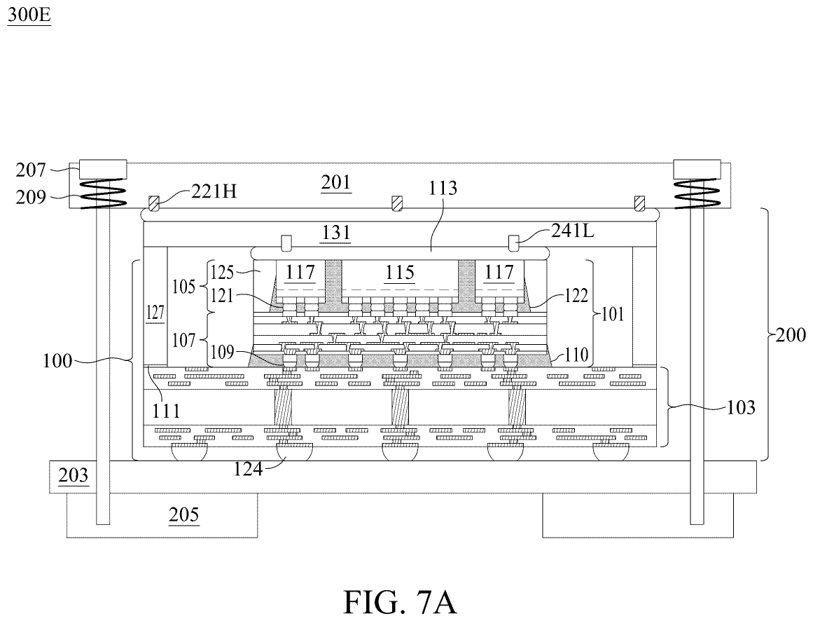

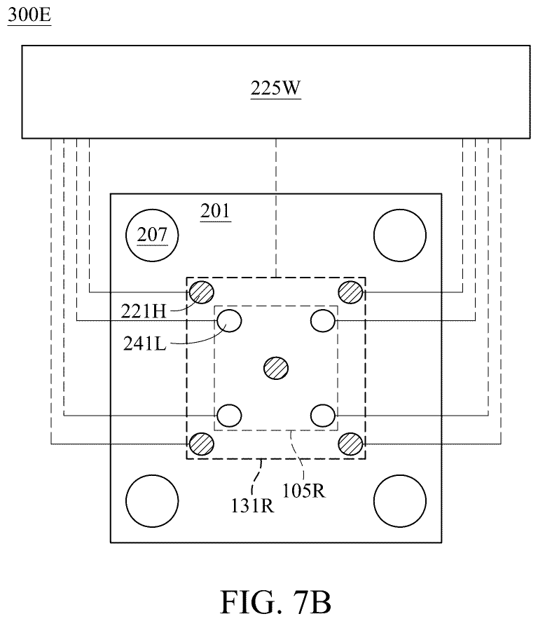

FIGS. 7A-7B illustrate a package system assembly 300E wherein either or both of the sensing modules 221H and sensing modules 241L along a lower surface of the package lid 131 are wireless, in accordance with various embodiments. The package system assembly 300E may be formed similarly and may comprise similar components as described above, unless otherwise stated. In particular, the package system assembly 300E may be analogous to any of the previous embodiments, albeit being free of the wires 223H/223L. For example, the package system assembly 300E may include the sensing modules 221H in the heat sink 201, the sensing modules 241L in the package lid 131, or both. FIG. 7B is a plan view illustrating an exemplary layout or configuration of the sensing modules 221H/241L, in accordance with some embodiments. However, the configuration for each set of sensing modules 221H/241L may have a same layout as analogous configurations of previous embodiments. Measurements from the sensing modules 221H/241L are sent as wireless signals (e.g., radio waves or any suitable frequency ranges) to a wireless monitoring system 225W.

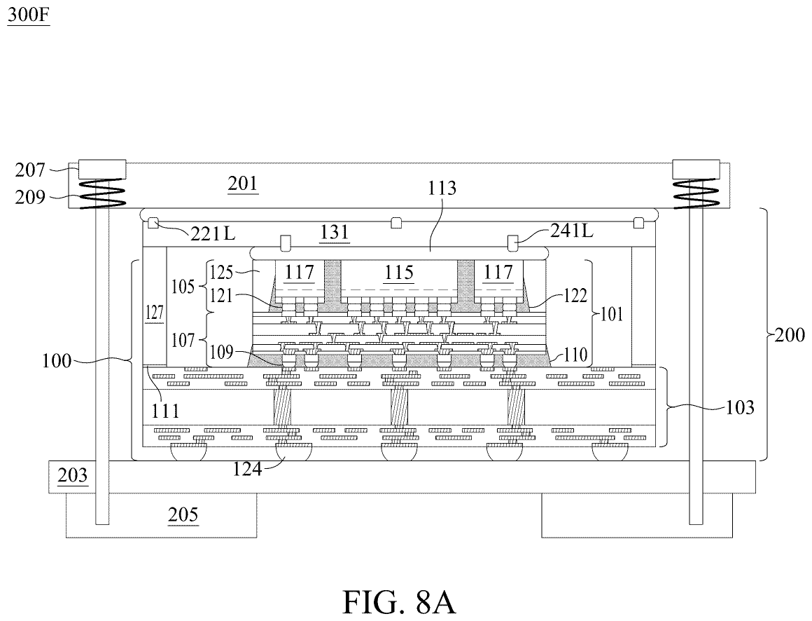

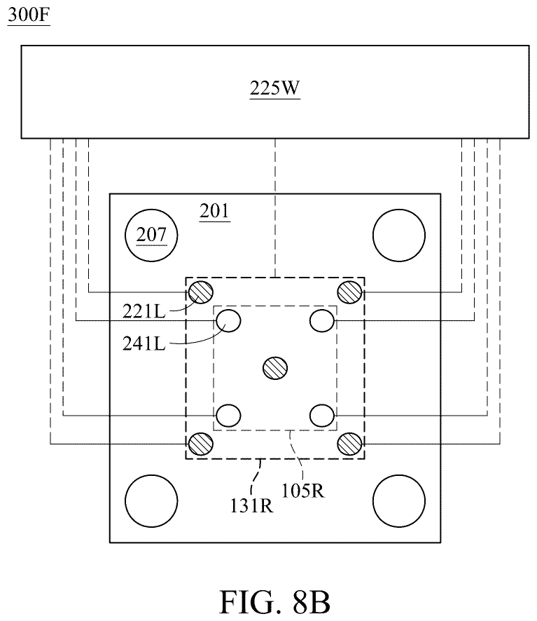

FIGS. 8A-8B illustrate a package system assembly 300F wherein the package lid 131 includes wireless sensing modules 221L along the upper surface and also wireless sensing modules 241L along a lower surface, in accordance with additional embodiments. The package system assembly 300F may be formed similarly and may comprise similar components as described above, unless otherwise stated. Each of the sensing modules 221L/241L may be configured to measure one or more of the properties discussed above. As illustrated, the heat sink 201 may be free of the sensing modules 221H. In some embodiments (not specifically illustrated), the heat sink 201 of the package system assembly 300B may also include the sensing modules 221H.

FIG. 8B is a plan view illustrating an exemplary layout or configuration of the sensing modules 221L/241L, in accordance with some embodiments. The selected configuration may be analogous to embodiments discussed above or any suitable pattern to facilitate measurement of the desired properties. For example, the sensing modules 221L may measure similar or different properties as the sensing modules 241L.

FIG. 8B illustrates the sensing modules 221L arranged on the upper surface of the heat sink 201 near the corners and at the center of the lid surface region 131R and the sensing modules 241L arranged on the lower surface of the package lid 131 along or near the sides of the chip module surface region 105R. In various embodiments (not specifically illustrated), each set of the sensing modules 221H/221L may have other suitable configurations (e.g., including those discussed in previous embodiments), and the respective configurations may be complementary or overlapping. However, the configuration for each set of sensing modules 221L/241L may have a same layout as analogous configurations of previous embodiments.

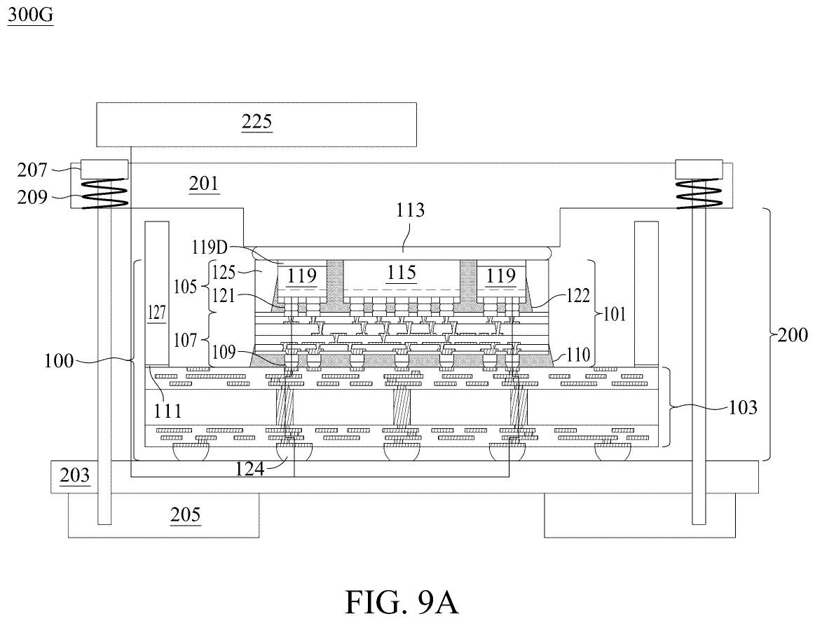

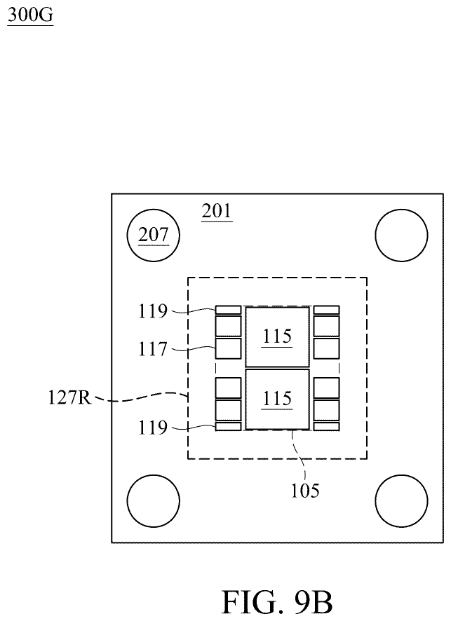

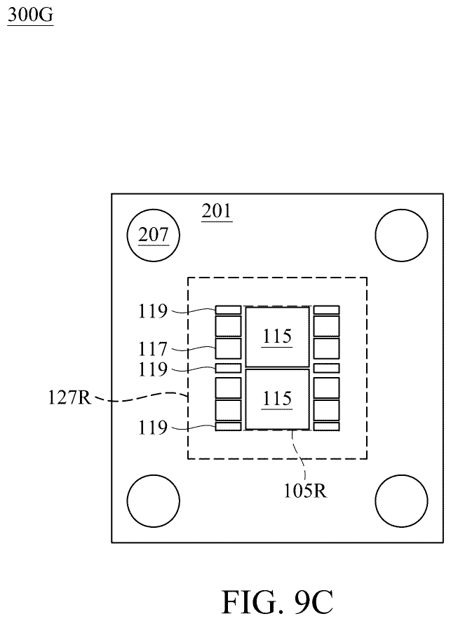

FIGS. 9A-9C illustrate a package system assembly 300G wherein the chip module 105 includes one or more sensor dies 119, in accordance with various embodiments. The sensor dies 119 may be configured to measure one or more of the properties discussed above. In some embodiments, the sensor dies 119 may include pressure sensor dies with strain gauge pressure sensors built into the sensor dies 119. The package system assembly 300G may be formed similarly and may comprise similar components as described above, unless otherwise stated. Although the package system assembly 300G is illustrated as being lidless (see, e.g., the lidless package system assembly 300D), the package system assembly 300G may include a package lid 131 as described in previous embodiments.

In various embodiments, the sensor dies 119 are dummy dies that include sensors 119D, e.g., in a region of the sensor die 119 adjacent to the first thermal interface material 113 when incorporated into the packaged arrangement 200. A remainder of the sensor die 119 may be dedicated to routing the measurement signals to the external connections 109, through the interposer 107, through the package substrate 103, through the assembly substrate 203, and to the monitoring system 225. In some embodiments (not specifically illustrated), the monitoring system 225 may be attached to the package substrate 103 or the assembly substrate 203. In some embodiments, the sensor dies 119 may be configured to measure pressures or pressure changes.

FIGS. 9B and 9C are plan views illustrating exemplary layouts or configurations of the sensor dies 119 of the chip module 105 as projected over the heat sink 201, in accordance with various embodiments. FIG. 9B illustrates the sensor dies 119 located at or near corners of the chip module 105, and FIG. 9C illustrates the sensor dies 119 located at or near the corners of the chip module 105 and also at sides of the chip module 105. However, any suitable configuration may be utilized.

Advantages may be achieved. Formation of the semiconductor system (e.g., into a package system assembly 300A, 300B, 300C, 300D, 300E, 300F or 300G) involves mounting larger thermally conductive components (e.g., the package lid 131, the thermal interface materials 113/213, the heat sink 201, and the assembly substrate 203) to smaller and more delicate semiconductor components (e.g., the semiconductor package 100). The foregoing embodiments disclose including at least some of the sensing modules 221/241 embedded in some of the thermally conductive components (e.g., the heat sink 201 and/or the package lid 131) to detect imbalances or deviations in other key performance indicators (KPIs) during the mounting of certain thermally conductive components (e.g., the heat sink 201). In addition, other sensing devices may be included in dummy dies 119 or integrated into the attachment of the heat sink 201 and the assembly substrate 203 for analogous KPI measurements. The various sensing devices allow for real-time measurement of KPIs to allow for fine-tuning and adjustments during the mounting process(es). As a result, the semiconductor system may be manufactured at a higher yield and to improved specifications.

In an embodiment, a method includes attaching a die to an interposer; attaching and electrically coupling the interposer to a package substrate; attaching a package lid and a first thermal interface material to the die and to the package substrate; attaching and electrically coupling the package substrate to an assembly substrate; and attaching a heat sink and a second thermal interface material to the package lid using a screw extending between the heat sink and the assembly substrate, the heat sink comprising first sensing modules in physical contact with the second thermal interface material. In another embodiment, the first thermal interface material is directly interposed between the package lid and the die. In another embodiment, a first thermal interface adhesive is directly interposed between the package lid and the package substrate. In another embodiment, the method further includes a bolt being threaded around the screw; and a pressure sensor being threaded around the screw, wherein the pressure sensor is interposed between the bolt and the assembly substrate. In another embodiment, in a plan view the first sensing modules are located at corners of a projection of a lid surface region. In another embodiment, the package lid comprises second sensing modules. In another embodiment, in the plan view the second sensing modules are located at sides of the lid surface region. In another embodiment, the die is a pressure sensing die. In another embodiment, the method further includes taking pressure measurements using the first sensing modules; and sending the pressure measurements to a pressure monitoring system. In another embodiment, the method further includes adjusting the screw based on the pressure measurements.

In an embodiment, a semiconductor device includes a printed circuit board; a semiconductor package disposed on the printed circuit board; a heat sink disposed on the semiconductor package; a first thermal interface material disposed between the semiconductor package and the heat sink; and first sensors disposed between the semiconductor package and the heat sink. In another embodiment, the first sensors are in contact with the first thermal interface material. In another embodiment, the semiconductor package includes a first die and a second die attached to an interposer; a package lid disposed over the first die and the second die, wherein the first thermal interface material is interposed between the first die and the package lid; and a second thermal interface material being interposed between the package lid and the heat sink. In another embodiment, the semiconductor device further includes second sensors, wherein the first sensors are in contact with the first thermal interface material, and wherein the second sensors in contact with the second thermal interface material. In another embodiment, the first die is a logic die, and wherein the second die is a pressure sensor die.

In an embodiment, a semiconductor device includes a semiconductor package comprising: a package substrate; and a package component attached and electrically connected to the package substrate; a first thermal interface material disposed over and physically contacting the package component; a package lid disposed over the first thermal interface material, the package lid comprising: a thermally conductive ring being attached to the package substrate; and a capping portion being in physical contact with the first thermal interface material; a heat sink disposed over the package lid, the heat sink comprising a first pressure sensor; and an assembly substrate disposed below and electrically connected to the package substrate. In another embodiment, the semiconductor device further includes a second thermal interface material interposed between the package lid and the heat sink. In another embodiment, the first pressure sensor physically contacts the second thermal interface material. In another embodiment, the semiconductor device further includes a second pressure sensor embedded in the package lid. In another embodiment, the second pressure sensor physically contacts the first thermal interface material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor package, the semiconductor package comprising:
a die attached to an interposer; and
the interposer attached to a package substrate;
attaching a first thermal interface material and a package lid over the semiconductor package, the first thermal interface material being directly interposed between the die and the package lid;
attaching a second thermal interface material and a heat sink over the package lid, wherein at least one of the heat sink and the package lid comprises a plurality of sensors; and
attaching the package substrate to an assembly substrate.
